(19) United States
(12) Patent Application Publication
(10) Pub. No.: US 2010/0097056 A1
(43) Pub. Date: Apr. 22, 2010

(54) METHOD AND APPARATUS FOR NANO-SCALE SQUID

(75) Inventors: Simon Kwai Hung Lam, New South Wales (AU); David Louis Tilbrook, New South Wales (AU); Peter Frederick Vohralik, New South Wales (AU)

Correspondence Address: NIXON & VANDERHYE, PC, 901 NORTH GLEBE ROAD, 11TH FLOOR, ARLINGTON, VA, 22203, US

(73) Assignee: COMMONWEALTH SCIENTIFIC AND INDUSTRIAL RESEARCH ORGANISATION, CAMPBELL (AU)

(21) Appl. No.: 12/310,397

(22) PCT Filed: Aug. 27, 2007
(86) PCT No.: PCT/AU2007/001234

§ 371 Date: Nov. 23, 2009

(30) Foreign Application Priority Data
Aug. 25, 2006 (AU) 2006904639

(51) Int. Cl. G01R 33/12; G01R 33/00

(52) U.S. Cl. 324/228; 324/260

(57) ABSTRACT

A nano-SQUID (superconducting quantum interference device) method and system for detecting a magnetic field associated with a nano-sample. A magnetic field of a nano-sample (1130) is coupled through the nano-SQUID hole/loop (720), by placing the sample within the SQUID loop. A static field (Bp) is applied across the nano-SQUID, substantially perpendicular to a sensitivity axis of the nano-SQUID. A perturbation field (Bm) is applied across the nano-SQUID, substantially perpendicular to the sensitivity axis of the nano-SQUID and substantially perpendicular to the static field. A behaviour of the magnetic field of the nano-sample caused by the static field and perturbation field is monitored by monitoring an output of the nano-SQUID. The nano-SQUID can be operated in open loop mode without flux locked loop.

### CROSS-REFERENCE TO RELATED APPLICATIONS

The present application claims priority from Australian Provisional Patent Application No 2006904639 filed on 25 Aug. 2006, the content of which is incorporated herein by reference.

### TECHNICAL FIELD

The present invention relates to measurement of a small magnetic field such as is produced by a small spin system, and in particular relates to a nano-SQUID system and method of operation of a nano-SQUID in order to measure such magnetic fields.

### BACKGROUND OF THE INVENTION

Superconducting quantum interference devices (SQUIDs) are seeing increasing use as highly sensitive magnetic field sensors. Such SQUID sensors are becoming increasingly popular due to the capabilities of high sensitivity sensing in areas such as geophysical mineral prospecting, biological magnetic field detection, with future applications potentially including single-spin measurement and control systems for quantum computers.

SQUIDs rely on use of one or more Josephson junctions. A Josephson junction is an interruption in a superconductor, through which tunnelling supercurrents can flow. In DC applications, a DC bias current is applied across the junction, to ensure a phase difference exists across the junction and that the desired electrical properties of the junction arise. Quantum interference causes the direct-tunnelling current across the junction to vary in the presence of an external magnetic field, such that junction current vs. applied field exhibits a Fraunhofer pattern.

To provide high sensitivity, DC SQUIDs are based on a superconducting ring interrupted by two Josephson junctions, forming a weakly connected superconducting loop. A DC SQUID is illustrated in FIG. 1. The superconducting ring 10 is interrupted by Josephson junctions 12 and 14. A voltage V of the DC SQUID varies with applied flux Φ_{A}. Such a configuration has significantly increased sensitivity to flux compared to either single DC biased Josephson junction on its own, due to a number of effects. First, interference effects between the Fraunhofer pattern of each junction yields a voltage waveform with a ‘beat’ periodicity many orders of magnitude narrower than the periodicity of each individual Fraunhofer pattern. Further, the effective area of the ring 10 is noticeably larger than the effective area of each individual junction, such that for a given field strength the DC SQUID is sensitive to significantly more flux than a Josephson junction alone.

The weakly connected superconducting loop 10 will contain flux only in multiples of the flux quantum nΦ₀, where n is an unknown integer and Φ₀ is 2.07×10⁻¹⁵ Wb. A resistor (not shown) is placed in parallel with each junction to eliminate hysteresis. In the DC SQUID, a change in applied flux Φ_{A} through the ring 10 leads to a phase difference across the junctions, giving rise to a detectable SQUID voltage V across the loop. If the bias current is held constant, the V-Φ_{A} curve is roughly sinusoidal, with the SQUID voltage V varying between Vₘᵢₙ, and Vₘₐₓ as the applied flux Φ_{A} varies between nΦ₀ and (n+½)Φ₀. Note the V-Φ_{A} curve is not a true sinusoid, as the envelope of the curve follows the very much wider Fraunhofer patterns. To minimise the effect of the Fraunhofer pattern envelope, SQUID designers utilise very narrow Josephson junctions, in order to produce a Fraunhofer pattern which is as wide as possible. For example, typical Josephson junctions now used produce a Fraunhofer pattern with a periodicity of perhaps 10⁻⁴ T.

The DC SQUID therefore acts as a sensitive but non-linear flux to voltage transducer. Due to the unknown value of n, such devices can only provide measurements of a value of flux relative to an unknown quiescent value.

However, providing for satisfactory noise performance of DC SQUIDs places tight constraints on numerous device characteristics. The noise performance of a DC SQUID, typically given in units of T/√Hz, is dependent on the current and inductance of the device, and for example may be unacceptably degraded when the SQUID loop inductance exceeds perhaps 30 pH. Such an exceedingly small inductance limit places a heavy constraint on SQUID loop area, also referred to as SQUID hole size, which has proved to be overly restrictive to continued use of DC SQUIDs.

Instead of DC SQUIDs, another type of device based on an interfering pair of Josephson junctions, termed a direct coupled magnetometer, is in use. The direct coupled magnetometer also utilises narrow Josephson junctions to provide for wide Fraunhofer patterns. To increase the effective area of the device, a pickup loop is employed as shown in FIGS. 2a and 2b.

FIG. 2a is a circuit diagram of a direct coupled magnetometer 20 having a pickup loop 22 comprising a single loop of a relatively wide superconducting track of low inductance. The pickup loop 22 is interrupted by a narrow gap 24, in which resides a pair of Josephson junctions 26, 28, as illustrated in more detail in FIG. 2b.

When exposed to a magnetic field, current is induced in the pickup loop 22. Current induced in the pickup loop 22 is injected into the very small SQUID loop 30 interrupted by the two Josephson junctions 26, 28. Loop 30 defines the size of the SQUID hole. The current induced in the pickup loop tends to simply flow through the uninterrupted superconducting portion of the small SQUID loop 30 and re-enter the pickup loop 22 without flowing through either Josephson junction 26, 28. Nevertheless, the presence of this relatively large current induced in the pickup loop 22 alters the phase relationships across the junctions 26, 28, and thus causes the output voltage of the device to shift.

The direct coupled magnetometer thus exploits the larger effective area of the pickup loop 22 without the problems of degradation in noise performance suffered by increasing the SQUID loop area or hole size. The SQUID hole size is made as large as possible within this constraint. Once again, the output of the direct coupled magnetometer 20 is a periodic function constrained within the envelope of the Fraunhofer patterns of the junctions 26, 28.

Linearity of a DC SQUID or a direct coupled magnetometer is usually achieved by use of a flux locked loop (FLL), of which many variations and refinements are possible, with a basic FLL circuit being illustrated by the circuit schematic of FIG. 3.

The current source 228 provides dc current bias for the SQUID 200 so that the SQUID output voltage is a periodic function of magnetic flux in the SQUID. A square wave (or possibly sinusoidal) current source 230, of typical frequency 100 kHz, provides flux modulation to the SQUID via coil 214. The SQUID output voltage is modulated at the same frequency as the flux with an amplitude and sign which depends on the quiescent magnetic flux Φ_{A} in the SQUID. The SQUID output signal is usually passed through an impedance matching circuit 260 (eg. a transformer or tuned circuit) to optimise signal/noise ratio, then an amplifier 242 and demodulator (eg. multiplier) 246 driven by a signal source 247 synchronous with the modulation of the current source 230. The output of the demodulator is a DC or slowly varying signal whose amplitude is proportional to the amplitude of the modulated signal from the SQUID. A negative demodulator output corresponds to a SQUID flux for which the slope of the voltage-flux characteristic is negative, and conversely for positive output.

The FLL is completed by signal conditioning circuits which may include an integrator 248 and amplifier 250 whose output produces a low-frequency current in the coil 214 via feedback resistor 261. The sense of the feedback is negative, ie., a positive applied flux produces a negative feedback flux, and vice versa, the net result being to lock the circuit onto a peak of the SQUID voltage-flux characteristic. The circuit output voltage 262 is proportional to the applied flux in the SQUID which is, in the case of a SQUID magnetometer, proportional to the relative applied magnetic field.

A RF SQUID is based on a superconducting ring interrupted by only one Josephson junction. When the superconducting ring is energised by an inductively coupled resonant RF-oscillator, tunnelling of electrons takes place at the junction and a periodic signal, being a function of flux through the ring, can be detected across the junction, due to the AC Josephson effect. The periodic signal is substantially a triangular waveform, usually having a period (ΔB) in the order of a nanotesla. Therefore, in order to yield a sensitivity in the femtotesla range, the RF SQUID is operated in a nulling bridge mode, or flux locked loop (FLL) mode, similar to the DC SQUID FLL mode. In this mode, magnetic flux is fed back to the SQUID so as to cause the output voltage to remain relatively constant. The feedback voltage, being proportional to the difference between the applied flux and the quiescent flux level, gives a highly accurate measurement of relative magnetic flux.

The feedback voltage V for a SQUID in FLL mode can therefore be written as

V=M(A_{eff}B+u) (1)

where

M is a constant in a specific SQUID system;

A_{eff} is the effective area of the SQUID;

B is the applied magnetic field; and

u is the quiescent flux.

As the FLL locks the SQUID onto an unknown point of the voltage-flux characteristic, it can be seen that the FLL SQUID measures only a relative value of magnetic field and not an absolute magnetic field value. Further, FLL SQUIDs have a maximum slew rate of the order of tens of kHz, above which the circuit loses ‘lock’, after which flux lock will be regained at an unknown and probably different quiescent value. To maximise the sensitivity of a SQUID to flux changes, it is desirable to maximise the area of the pickup loop 22 (also referred to as an input coil), within inductance constraints, and in the case of RF SQUIDs while maintaining good coupling of the pickup loop flux transformer to the SQUID loop.

Use of a pickup loop and flux transformer is also attractive because the configuration of the pickup loops and flux transformer further provides flexibility in selecting which field characteristic is measured. For example, FIG. 4 illustrates a pickup loop configured to act as a magnetometer measuring B_{z}, while FIG. 5 illustrates a pickup loop configured to act as a first order gradiometer, measuring ΔB_{z}/Δz. Higher order gradiometer configurations are also possible.

There is a growing interest in the measurement of small spin systems, and some efforts have focused on the use of SQUIDs for measuring such systems. However, difficulties in using a SQUID for such applications include the requirement for very high spin sensitivity and wide operating frequency range.

Any discussion of documents, acts, materials, devices, articles or the like which has been included in the present specification is solely for the purpose of providing a context for the present invention. It is not to be taken as an admission that any or all of these matters form part of the prior art base or were common general knowledge in the field relevant to the present invention as it existed before the priority date of each claim of this application.

Throughout this specification the word “comprise”, or variations such as “comprises” or “comprising”, will be understood to imply the inclusion of a stated element, integer or step, or group of elements, integers or steps, but not the exclusion of any other element, integer or step, or group of elements, integers or steps.

### SUMMARY OF THE INVENTION

According to a first aspect the present invention provides a method of operation of a nano-SQUID to detect a magnetic field associated with a sample, the method comprising:

magnetically coupling the field of the sample through the nano-SQUID hole;

applying a static field across the nano-SQUID, substantially perpendicular to a sensitivity axis of the nano-SQUID;

applying a perturbation field across the nano-SQUID, substantially perpendicular to the sensitivity axis of the nano-SQUID and substantially perpendicular to the static field; and

monitoring an output of the nano-SQUID corresponding to a behaviour of the magnetic field of the sample caused by the static field and time varying field.

According to a second aspect, the present invention provides a nano-SQUID system for detecting a magnetic field associated with a sample, the system comprising:

a nano-SQUID;

a sample having a magnetic field coupled through the nano-SQUID hole;

a first field generator for generating a static field across the nano-SQUID, substantially perpendicular to a sensitivity axis of the nano-SQUID;

a second field generator for generating a perturbation field across the nano-SQUID, substantially perpendicular to the sensitivity axis of the nano-SQUID and substantially perpendicular to the static field; and

a monitor for monitoring an output of the nano-SQUID corresponding to a behaviour of the magnetic field of the sample caused by the static field and perturbation field.

Importantly, the present invention recognises that a small spin system may be positioned substantially within the hole of the nano-SQUID itself, in a position in which the magnetic field of the system is coupled through the hole of the SQUID, thus eliminating the use of a flux transformer. Further the present invention utilises a polarising (static) field and a perturbation field in order to perturb the magnetic moment of the sample, which in turn alters the field coupled through the nano-SQUID hole, thus inducing measurable changes in the output of the nano-SQUID.

A SQUID is a nano-SQUID in accordance with the invention when the size of the SQUID hole is made small, for example to nanometre size, to provide for measurement of small local fields. This is in contrast to conventional SQUIDs in which the SQUID hole is made as large as inductance and noise limits allow. An advantage in using a nano-SQUID is that the extremely small SQUID hole size makes the device significantly more insensitive to ambient fields. Thus, the present invention recognises that a relatively large polarising or static field, and a relatively large perturbation field may be used in order to perturb the magnetic moment of the sample in a defined manner, with the nano-SQUID being sufficiently insensitive to such relatively large fields aligned substantially orthogonally to the sensitivity axis of the nano-SQUID that detection of the substantially smaller field associated with the sample may still be achieved by the nano-SQUID.

Still further, improved insensitivity to ambient fields allows the device to be substantially more sensitive to field changes occurring during or very soon after changes in the perturbation field. For example changes which occur following on-off switching of a periodic pulsed perturbation field. This enables some embodiments of the invention to detect spins which precess rapidly, for example within 20 μs or less of switching of a pulsed field.

The perturbation field is preferably a pulsed, periodic field, such as an RF pulse train.

The nano-SQUID preferably comprises a thin-film nano-device comprising Josephson junctions formed of nanobridges. Such embodiments are advantageous as thin-film fabrication techniques such as electron beam lithography and reactive ion etching allow the nano-SQUID hole size to be made small, for example the nano-SQUID hole may be of submicron diameter. In further such embodiments, a normal conducting layer such as gold is preferably provided over the nanobridges to resistively shunt the nanobridges and eliminate hysteresis.

In embodiments where the Josephson junctions are resistively shunted to eliminate hysteresis, the monitored output of the nano-SQUID is preferably the SQUID voltage, with a constant bias current being applied across the nano-SQUID. Such embodiments are advantageous compared to embodiments in which the monitored output is the change in junction critical current, as the bandwidth and SQUID sensitivity is substantially improved when SQUID output voltage is monitored.

Further embodiments may be operated at reduced temperatures, for example in a dilution refrigerator, in order to improve spin sensitivity. Additionally or alternatively, a SQUID amplifier may be provided in order to minimise the effects of amplifier noise, to reduce the output noise floor and thus improve spin sensitivity.

The present invention recognises the desirability of providing a very small nano-SQUID hole size, as spin sensitivity is proportional to SQUID hole size. For example, embodiments comprising an extremely small SQUID hole size of ˜200 nm diameter may have a spin sensitivity of 250 spin/Hz^{1/2} (in terms of Bohr magneton) at 4.2 K.

Preferably, the nano-SQUID is operated in an open loop mode, such that the nano-SQUID functions as a flux-to-voltage converter. Such embodiments eliminate the requirement for a flux locked loop, and simplify readout requirements. Further, such embodiments recognise that the present invention functions in the small flux regime of Φ<<Φₒ, where Φ is the magnetic flux seen by the SQUID and Φₒ is the flux quantum (Φₒ=2.07×10⁻¹⁵ Tm). Accordingly, while open loop operation is generally considered to be best avoided in most SQUID applications due to the non-linear response, the regime of operation of embodiments of the invention involves magnetic flux quantities of much less than one flux quantum being coupled through the device, so that the transfer function of the nano-SQUID in this regime can be expected to have a roughly linear characteristic, even when operating in an open loop mode.

The sample may be mounted by electron beam induced deposition (EBID) by scanning electron microscope (SEM). The sample may comprise a contamination resist, formed from residual carbon and hydrogen-rich material present in a vacuum chamber following etching and lithographic fabrication of the nano-SQUID superconducting tracks and conductive layer. Alternatively, the sample may comprise a metallic nanostructure formed by injecting vaporised metallic precursors into the path of the electron beam column. Such embodiments of the invention thus provide a technique for addressing the difficulty in placing a small spin system in a position of sensitivity relative to the nano-SQUID hole.

The sample may be positioned substantially in the centre of the nano-SQUID hole, or alternatively may be positioned non centrally in the nano-SQUID hole, proximal to the SQUID loop to improve flux coupling.

### BRIEF DESCRIPTION OF THE DRAWINGS

An example of the invention will now be described with reference to the accompanying drawings, in which:

FIG. 1 illustrates a DC SQUID;

FIGS. 2a and 2b illustrate a direct coupled magnetometer;

FIG. 3 illustrates a flux locked loop for a DC SQUID;

FIG. 4 illustrates a flux transformer configured as a magnetometer;

FIG. 5 illustrates a flux transformer configured as a first order gradiometer;

FIG. 6 illustrates a nano-SQUID system in accordance with the present invention;

FIG. 7 is a scanning electron microscope image of a nano-SQUID suitable for use in the present invention;

FIG. 8 shows the output voltage of the nano-SQUID at different bias currents when an AC modulated calibration field is applied perpendicular to the plane of the nano-SQUID;

FIG. 9 shows the variation in the peak to peak output voltage of the nano-SQUID when varying the peak to peak amplitude of the calibration field;

FIG. 10 illustrates flux noise of the nano-SQUID system in the absence and presence of a polarising field Bₚ;

FIG. 11 is a scanning electron microscopy image of a nano-SQUID in accordance with another embodiment of the invention, having a deposited EBID CR patch positioned in the centre of the nano-SQUID hole.

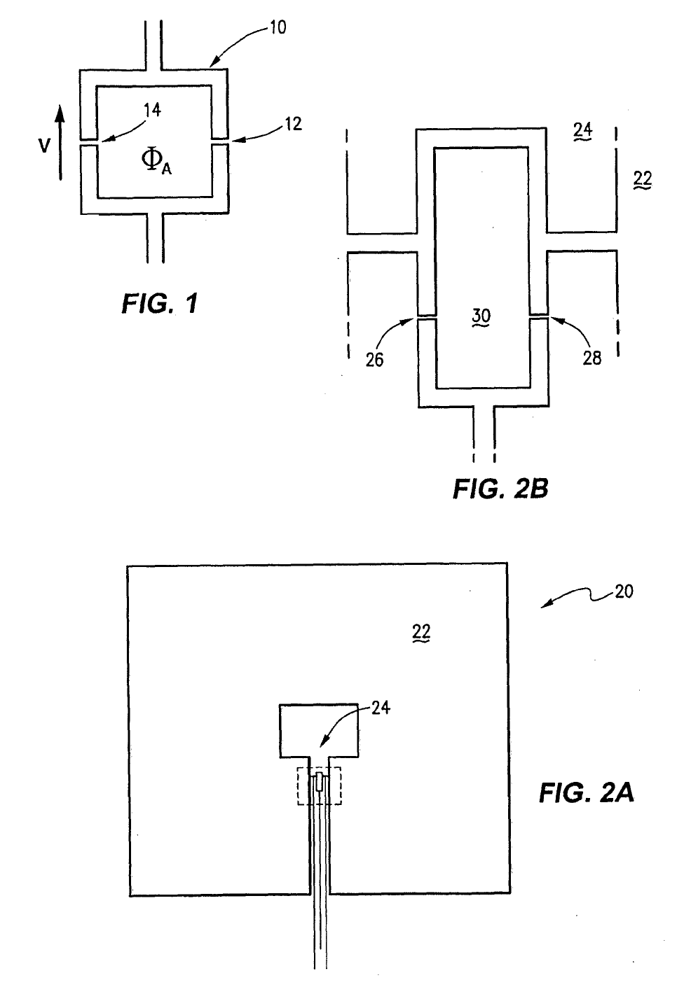

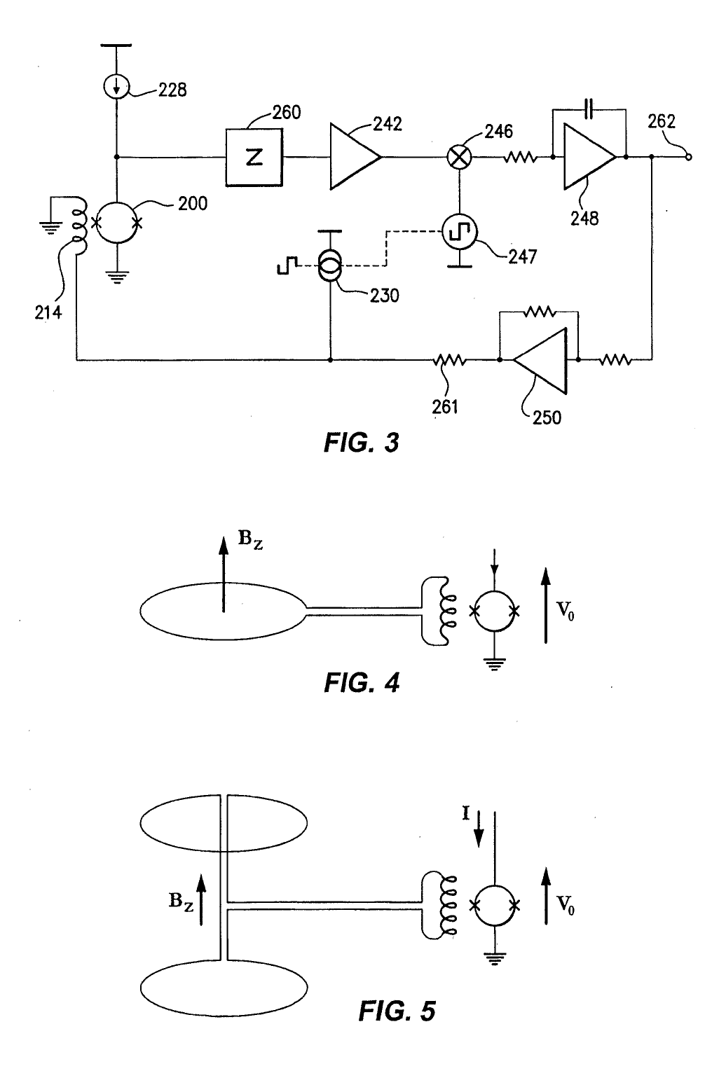

### DESCRIPTION OF THE PREFERRED EMBODIMENTS

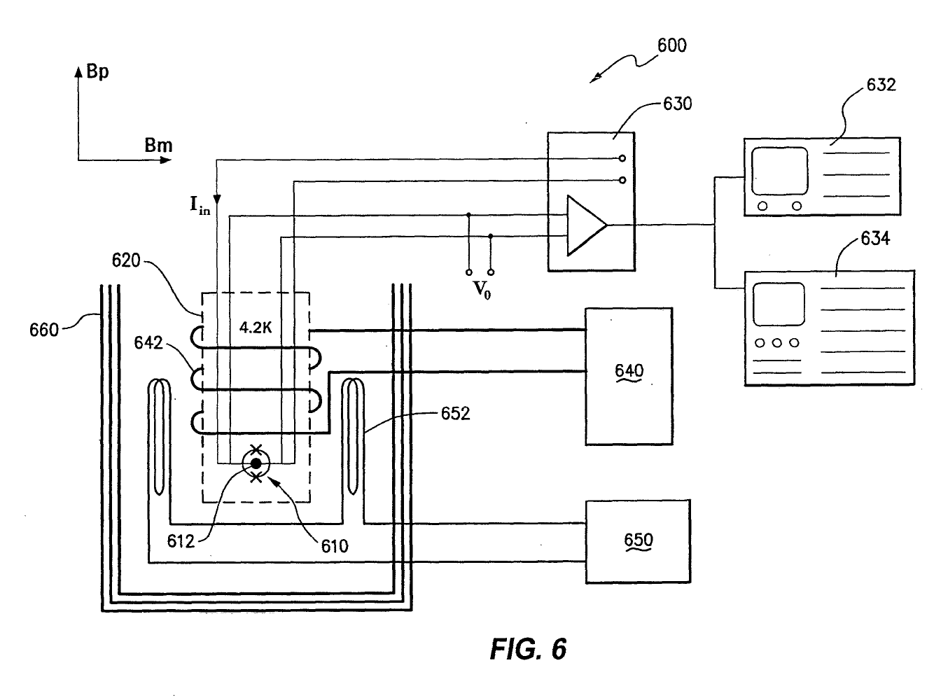

FIG. 6 illustrates a nano-SQUID system 600 in accordance with an embodiment of the present invention. A nano-SQUID 610 has a sample 612 mounted within the nano-SQUID hole. A dewar 620 maintains the nano-SQUID 610, sample 612, and associated electronics at a temperature of 4.2K. The nano-SQUID 610 is mounted on a chip carrier of a probe and cooled at liquid helium temperatures inside the tail of the glass fiber dewar without any magnetic shielding.

Squid electronics 630 provide the appropriate bias current retrieve the output voltage Vₒ of the nano-SQUID and amplify that voltage with a room temperature amplifier for assessment by the digital oscilloscope 632 and the spectrum analyser 634. Notably, in this embodiment the nano-SQUID 610 is dc current-biased just above its critical current as discussed further in the following.

Two sets of coils 642 and 652 are wound outside the tail of the dewar 620 to provide the magnetic field for the calibration of the flux sensitivity of the nano-SQUID 610 and to provide the magnetic fields for a NMR measurement scheme. A constant power supply 640 drives a constant current through coil 642 to generate a static polarising field Bₚ in the y direction. A pulse generator 650 drives current pulses through coil 652 to produce a pulsed magnetization field Bₘ in the x direction which perturbs the magnetic moment of the sample 612 from a state defined by the static field Bₚ. Bₚ and Bₘ are orthogonal to the sensitivity axis of the nano-SQUID, which is aligned along the z-axis, out of the page.

System 600 further comprises a 3 layer mu-metal shield 660.

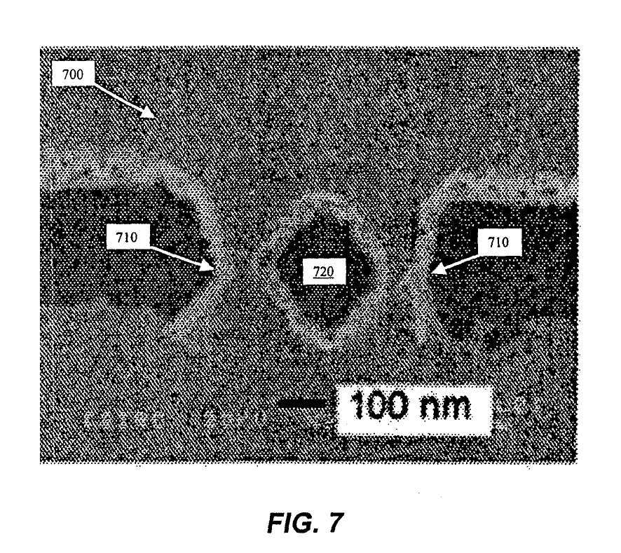

FIG. 7 is a scanning electron microscope image of a nano-SQUID 700 suitable for use as nano-SQUID 610 in the system 600 of FIG. 6. Nano-SQUID 700 comprises two nanobridges 710 which define a diamond-shaped nano-SQUID hole 720. The nano-SQUID 700 of FIG. 7 comprises a superconducting niobium underlayer, and the Josephson junctions in the niobium layer of the nanobridges 710 are non-hysteretic due to the presence of a shunting Au overlayer. The shunting resistance of the Au overlayer is about 2Ω.

The fabrication process and the geometry of the nano-SQUID are described here. The thickness of the Nb and Au thin films were 20 and 25 nm respectively. The Au overlayer was used as an etching mask as well as a protective layer for the Nb film to prevent oxidation. Electron-beam lithography was used to pattern the nano-SQUID 700 whereas the electrical contacts (not shown) were patterned by standard photolithography. The two nanobridges 710 have a width of around 70 nm, giving a total critical current of around 50 μA. The nano-SQUID has a hole of size ˜200 nm×200 nm and washer area (not shown) of ˜3 μm×3 μm.

The non-hysteretic behaviour of the nano-SQUID 700 makes it possible to operate the system 600 using SQUID output voltage detection techniques, thus providing a wide bandwidth for applications such as the nuclear magnetic resonance (NMR) configuration of FIG. 6, or in other applications such as quantum computing.

It is further noted that an important recognition of the present embodiment of the invention is that an open-loop mode of operation of the nano-SQUID 610, in which the nano-SQUID 610 is used as a small signal flux-voltage converter, has been found to be functional. Previously, open loop operation has been considered to be inappropriate due to the non-linear response of the device to changes in Φ, the magnetic flux seen by the SQUID. However, the present invention recognises that, as the nano-SQUID 610 is intended to measure very small magnetic fields from a local nano-scale object 612, the magnetic flux coupled onto the device is anticipated to be much smaller than one flux quantum (Φ<<Φₒ, where Φₒ is the flux quantum Φₒ=2.07×10⁻¹⁵ Tm). In such a small-flux regime, the operating range of a nano-SQUID in fact has a transfer function close to a linear characteristic. The open loop mode of operation simplifies the readout scheme, and allows significantly improved exploitation of the natural large bandwidth of the nano-SQUID 610. In some embodiments an excellent frequency range from DC to GHz frequencies may be achievable.

While the nano-SQUID 700 thus exhibits desirable characteristics, there nevertheless exists further challenges in using it in the measurement of small spin systems. These challenges include the noise properties of the device 700 in the static field environment provided by the coil 642 of the system 600 of FIG. 6, and the challenge of positioning the sample 612, which may comprise a nanoparticle or molecule, onto the device's surface within the nano-SQUID hole 720.

We first address the challenge of noise properties. When nano-SQUID 700 is employed in the place of nano-SQUID 610 in the system 600 of FIG. 6, the optimum bias current is obtained by observing the maximum output voltage Vₒ when a small AC modulated calibration field is applied perpendicular to the plane of the SQUID 610 by a coil (not shown). Commercial dc SQUID electronics (Star Cryoelectronic) were used to perform the noise measurements.

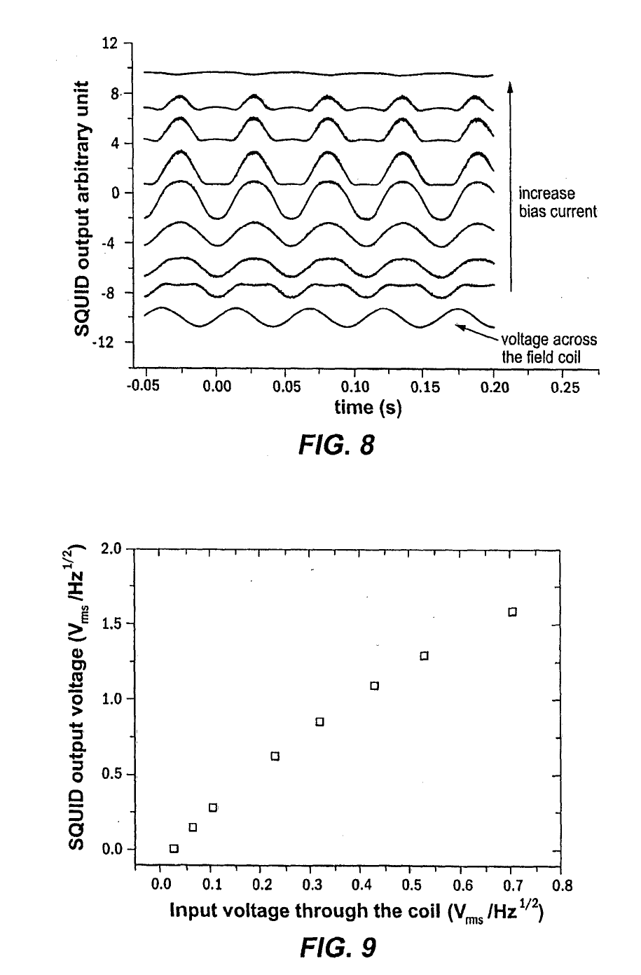

FIG. 8 shows the output voltage of the nano-SQUID 700 at different bias currents when an AC modulated calibration field was applied perpendicular to the plane of the device. The peak-to-peak amplitude of the field is ˜100 μT, corresponding to a flux of ˜80 mΦₒ coupled to the nano-SQUID 700. The voltage across the magnetic field coil (not shown) and the output voltage Vₒ of the device at the modulation frequency were measured by a spectrum analyser. FIG. 8 shows that, with increasing bias current, the peak to peak amplitude of Vₒ induced by the calibration field increases to a maximum at the ideal bias current, and then begins to decrease as bias current increases beyond the ideal level. Thus, the ideal bias current can be determined by this method.

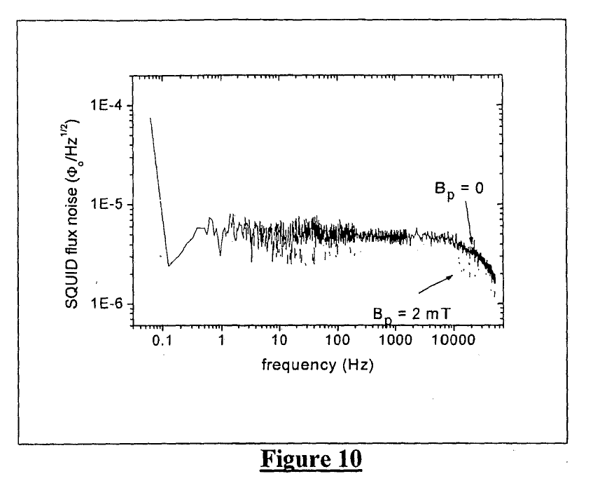

The flux-to-voltage transfer function of nano-SQUID 700 was then obtained by measuring the peak to peak level of Vₒ, while varying the peak to peak amplitude of the calibration field, and keeping the bias current at the previously identified ideal level. FIG. 9 shows the measured data using a field modulated at a frequency of 17.75 Hz. The transfer function was calculated to be ˜3.0 mV/Φₒ for the lower input regime (input flux <5 mΦₒ), to a value of ˜2.0 mV/Φₒ for the higher input regime (input flux >40 mΦₒ).

As the flux state of the SQUID can lie at any point on its periodic voltage-flux characteristic, a permanent magnet was introduced to provide an extra flux of maximum ˜0.5 Φₒ on the plane of the nano-SQUID to identify the flux state of the device qualitatively. It was noticed that the flux state of the nano-SQUID had been at the steepest point on its characteristic, i.e., Φ=0.5 nΦₒ (n=0, 1, 2 . . . ), where the transfer function has the highest value.

The flux noise of nano-SQUID 700 was calculated by dividing the measured voltage noise with the transfer function, the results of which are shown in FIG. 10. The measured voltage noise of the device was 1.8×10⁻⁸ V/Hz^{1/2}, which is worse (higher) than the noise level of the SQUID electronics (1×10⁻⁹ V/Hz^{1/2}). A flux noise of 5.2×10⁻⁶ Φₒ/Hz^{1/2} was obtained at frequencies less than 1 Hz. This corresponds to a spin sensitivity of ˜200 spins/Hz^{1/2} (in units of Bohr magneton) at 4.25 K. The bandwidth was about 30 kHz, which was limited by the SQUID electronics. It is to be noted that nuclear spins are about 1000 times weaker than electron spins and therefore, the nuclear spin sensitivity would be ˜2×10⁵ spins/Hz^{1/2}.

The flux noise of the nano-SQUID 700 in the presence of the polarising field Bₚ was also determined. As shown in FIG. 10, for a field strength Bₚ=2 mT, the flux noise did not change significantly, with an increase of ˜15% noted at low frequencies (below 5 Hz). The optimal point for the biasing current in the presence of a field strength Bₚ=2 mT also did not change. Thus, the nano-SQUID 700 gives promising noise results for use in the system 600.

Returning now to the NMR measurement scheme and system of FIG. 6, it can be seen that static (Bₚ) and radio frequency (Bₘ) magnetic fields are to be applied orthogonal to the sensitive axis of the nano-SQUID. We define the axis perpendicular to the plane of the nano-SQUID 610 as the z-axis, such that the static and radio frequency fields will be applied in x and y directions respectively. In the case of pulse NMR, the resonance signal from the spin system 612 will be detected after the radio frequency pulse field Bₘ is removed, in which the nuclear spin precesses back to the static field Bₚ direction. In the embodiment shown, a maximum Bₚ field limitation of ˜2.5 mT applied due to the Joule-heating effect on the wire of coil 642.

These results are promising for low-field NMR nano-SQUID experiments as they reveal that the nano-SQUID operates well in static magnetic Bₚ fields of up to 2 mT, thus providing for a regime of operation of nano-SQUID NMR in which the precession frequency is 1 Hz-100 kHz relative to proton. The present invention recognises that this promising performance is achieved due to Bₚ being applied parallel to the plane of the nano-SQUID and the effective area of the nano-SQUID being extremely small (˜5×10⁻¹³ m²).

For proton NMR measurement using a nano-SQUID detector with a substantially lower Bₚ field strength of the order of a few micro-teslas, the precession frequency is in the order of 100 Hz, such that a small measurement bandwidth of a few Hz can be expected. Considering the characteristics of nano-SQUID 700, for a 10 Hz bandwidth measurement at low frequency, the minimum detectable nuclear spin (Sₘ) of system 600 can be estimated to be ˜6×10⁵. An estimate for a 100 nm ½-spin Pt particle that has ˜10⁷ atoms gives the total nuclear spin as 5×10⁶. Therefore with optimum coupling and optimal device design the present invention may be expected to be suitable for low-field NMR measurements on nanoparticles and molecules with proton spin of ˜10⁷. Even allowing for non-optimal coupling, the anticipated Sₘ of ˜6×10⁵ should allow for detection of a cluster of a number of such particles, as would operation at much reduced temperatures such as the milli-Kelvin regime.

Thus, the present invention recognises that in order to obtain a high spin sensitivity, the SQUID flux noise must be low and the hole size of the SQUID has to be very small, as the spin sensitivity is proportional to these two parameters.

We now turn to techniques for the positioning of small spin systems such as nanoparticles and molecules into the nano-SQUID hole for such spin measurements. One such technique which may be used in order to position a small system into the nano-SQUID hole in accordance with one embodiment of the invention, is electron beam induced deposition (EBID) using a scanning electron microscope (SEM). The present embodiment of the invention recognises that this technique is an inexpensive way to make maskless nanometre-size resist structures. In this technique, a ‘contamination’ resist (CR) is formed by the adsorption of residual hydrocarbon contamination gases on the sample surface inside the SEM chamber and decomposed by beam-induced surface reactions, resulting in the localized deposition of carbon and hydrogen-rich material on the surface where the electron beam has scanned. Metallic nanostructures can also be made directly using EBID by metalorganic precursors, which are vaporized and injected into the path of the electron beam column.

EBID has been performed in order to deposit a CR patch inside a nano-SQUID hole, with a view to measure the NMR of protons of the CR patch. The same SEM was used for e-beam lithography and to perform the EBID CR patch deposition. The deposition and imaging are performed at the same time by switching the SEM between imaging and lithography mode. No alignment marker was required as we used the cursor marker of the SEM to position the device before the deposition.

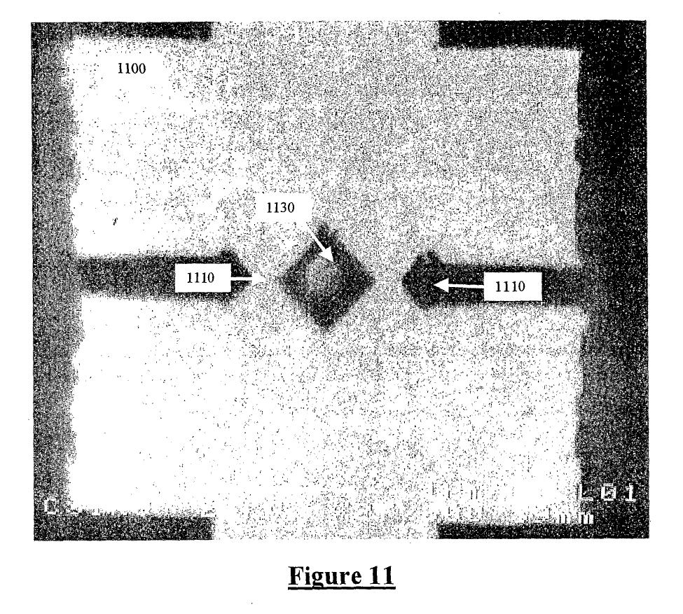

FIG. 11 shows a nano-SQUID 1100 in accordance with a second embodiment of the invention, with nanobridges 1110 defining a nano-SQUID hole. This nano-SQUID test structure has a bigger hole size (˜600 nm×600 nm) than the device of FIG. 7. The SEM image of FIG. 11 further shows a CR patch 1130 of diameter ˜200 nm at a magnification of 1000 during EBID. It shows that the alignment accuracy in positioning the CR patch in the desired central location is less than 50 nm. Further, it is considered that accuracy will be improved down to less than 20 nm when the EBID is performed at a high magnification. This technique is further advantageous in being simple, and can also be used to deposit patches of different sizes by changing the total electron charge dosage on the scan area, in which we can study the minimum detectable size of the CR patch.

It is further noted that the existing spin sensitivity of nano-SQUID 700 is based on the calculation of the spin signal from the centre of the SQUID hole. Stronger coupling may be achieved when the spin system is positioned near the edge of the SQUID hole.

Thus, NMR detection of nano-scale objects using the above-described nano-SQUID, and accompanying system design, is particularly attractive for a number of reasons. Firstly, the magnetic object or sample can be placed directly into the SQUID hole which eliminates the flux transformer used for conventional SQUID applications. Furthermore, while a large-static magnetic field may be applied during the NMR spin measurement, the nano-SQUID nevertheless operates with low noise under this condition, as the washer size of the nano-SQUID is only a few microns in width, so that the SQUID itself is relatively insensitive to the static field. A further advantage of this static field insensitivity of the nano-SQUID is that, because the static field determines the frequency of the NMR signal, a larger allowable range of static field allows a broader detection bandwidth. Hence, a larger number of different elements with different precession frequencies can be detected at the same time.

It is further noted that, while some applications including quantum computing require sensitivity to spin at the Bohr magneton level, fabrication of a nano-SQUID having smaller hole dimensions and/or improved noise performance offers the promise of producing spin sensitivities approaching such levels. Use of a SQUID amplifier is one way in which noise performance of the system 600 may be improved. Thus, the present invention shows promise in moving towards such applications.

It will be appreciated by persons skilled in the art that numerous variations and/or modifications may be made to the invention as shown in the specific embodiments without departing from the spirit or scope of the invention as broadly described. The present embodiments are, therefore, to be considered in all respects as illustrative and not restrictive.

1. A method of operation of a nano-SQUID to detect a magnetic field associated with a sample, the method comprising:
magnetically coupling the field of the sample through the nano-SQUID hole;
applying a static field across the nano-SQUID, substantially perpendicular to a sensitivity axis of the nano-SQUID;
applying a perturbation field across the nano-SQUID, substantially perpendicular to the sensitivity axis of the nano-SQUID and substantially perpendicular to the static field; and
monitoring an output of the nano-SQUID corresponding to a behaviour of the magnetic field of the sample caused by the static field and time varying field.

2. The method of claim 1 wherein the perturbation field is a pulsed periodic field.

3. The method of claim 2 wherein the perturbation field is an RF pulse train.

4. The method of claim 1 wherein the nano-SQUID comprises a thin-film nano-device comprising Josephson junctions formed of nanobridges.

5. The method of claim 4 wherein the nanobridges are resistively shunted to eliminate hysteresis.

6. The method of claim 5 wherein a normal conducting layer is provided over the nanobridges for resistive shunting.

7. The method of claim 4 wherein the monitored output of the nano-SQUID is the SQUID voltage, with a constant bias current being applied across the nano-SQUID.

8. The method of claim 1 when conducted at reduced temperatures, for example in a dilution refrigerator, in order to improve spin sensitivity.

9. The method of claim 1 further comprising providing a SQUID amplifier to minimise the effects of amplifier noise, to reduce the output noise floor and improve spin sensitivity.

10. The method of claim 1 wherein the SQUID hole is less than one micron in diameter.

11. The method of claim 10 wherein the SQUID hole is substantially 200 nm in diameter.

12. The method of claim 1 wherein the nano-SQUID is operated in an open loop mode, such that the nano-SQUID functions as a flux-to-voltage converter.

13. The method of claim 1 wherein the sample is mounted by electron beam induced deposition (EBID) by scanning electron microscope (SEM).

14. The method of claim 1 wherein the sample comprises a portion of contamination resist, formed from residual carbon and hydrogen-rich material present in a vacuum chamber following etching and lithographic fabrication of the nano-SQUID superconducting tracks and conductive layer.

15. The method of claim 1 wherein the sample comprises a metallic nanostructure formed by injecting vaporised metallic precursors into the path of an electron beam column.

16. The method of claim 1 wherein the sample is positioned substantially in the centre of the nano-SQUID hole.

17. The method of claim 1 wherein the sample is positioned non centrally in the nano-SQUID hole, proximal to the SQUID loop to improve flux coupling.

18. A nano-SQUID system for detecting a magnetic field associated with a sample, the system comprising:
a nano-SQUID;
a sample having a magnetic field coupled through the nano-SQUID hole;
a first field generator for generating a static field across the nano-SQUID, substantially perpendicular to a sensitivity axis of the nano-SQUID;
a second field generator for generating a perturbation field across the nano-SQUID, substantially perpendicular to the sensitivity axis of the nano-SQUID and substantially perpendicular to the static field; and
a monitor for monitoring an output of the nano-SQUID corresponding to a behaviour of the magnetic field of the sample caused by the static field and perturbation field.

19. The system of claim 18 wherein the perturbation field is a pulsed periodic field.

20. The system of claim 19 wherein the perturbation field is an RF pulse train.

21. The system of claim 18 wherein the nano-SQUID comprises a thin-film nano-device comprising Josephson junctions formed of nanobridges.

22. The system of claim 21 wherein the nanobridges are resistively shunted to eliminate hysteresis.

23. The system of claim 22 wherein a normal conducting layer is provided over the nanobridges for resistive shunting.

24. The system of claim 21 wherein the monitored output of the nano-SQUID is the SQUID voltage, with a constant bias current being applied across the nano-SQUID.

25. (canceled)

26. The system of claim 18 further comprising providing a SQUID amplifier to minimise the effects of amplifier noise, to reduce the output noise floor and improve spin sensitivity.

27. The system of claim 18 wherein the SQUID hole is less than one micron in diameter.

28. The system of claim 27 wherein the SQUID hole is substantially 200 nm in diameter.

29. The system of claim 18 wherein the nano-SQUID is operated in an open loop mode, such that the nano-SQUID functions as a flux-to-voltage converter.

30. The system of claim 18 wherein the sample is mounted by electron beam induced deposition (EBID) by scanning electron microscope (SEM).

31. The system of claim 18 wherein the sample comprises a portion of contamination resist, formed from residual carbon and hydrogen-rich material present in a vacuum chamber following etching and lithographic fabrication of the nano-SQUID superconducting tracks and conductive layer.

32. The system of claim 18 wherein the sample comprises a metallic nanostructure formed by injecting vaporised metallic precursors into the path of an electron beam column.

33. The system of claim 18 wherein the sample is positioned substantially in the centre of the nano-SQUID hole.

34. The system of claim 18 wherein the sample is positioned non centrally in the nano-SQUID hole, proximal to the SQUID loop to improve flux coupling.
